(19) United States
(12) Patent Application Publication
(10) Pub. No.: US 2009/0134014 A1
(43) Pub. Date: May 28, 2009

(54) Method for forming a transparent electroconductive film

(75) Inventors: Hirohisa Takahashi, Sammu-shi (JP); Sadayuki Ukishima, Sammu-shi (JP); Atsushi Ota, Sammu-shi (JP); Noriaki Tani, Sammu-shi (JP); Satoru Ishibashi, Sammu-shi (JP)

Correspondence Address: KRATZ, QUINTOS & HANSON, LLP, 1420 K Street, N.W., Suite 400, WASHINGTON, DC, 20005, US

(73) Assignee: ULVAC, INC., Chigasaki-shi (JP)

(21) Appl. No.: 12/359,694

(22) Filed: Jan. 26, 2009

Related U.S. Application Data
(63) Continuation of application No. PCT/JP2007/064705, filed on Jul. 26, 2007.

(30) Foreign Application Priority Data
Jul. 28, 2006 (JP) 2006-205937

(51) Int. Cl. C23C 14/34

(52) U.S. Cl. 204/192.15

(57) ABSTRACT

A transparent electroconductive film having a low resistivity is provided. In a film-forming method of the present invention, a transparent electroconductive film is formed on a surface of a substrate by sputtering, in a vacuum atmosphere, a target in which ZnO is a main component and Al₂O₃ and B₂O₃ are added, and then the transparent electroconductive film is annealed by the heating thereof at a temperature of 300° C. or more and 400° C. or less. The resistivity of the obtained transparent electroconductive film is reduced because the film has ZnO as the main component and Al and B added thereto. The transparent electroconductive film formed by the present invention is suitable as a transparent electrode for the FDP, etc.

This is a Continuation of International Application No. PCT/JP2007/064705 filed Jul. 26, 2007, which claims priority to Japan Patent Application No. 2006-205937, filed on Jul. 28, 2006. The entire disclosures of the prior applications are hereby incorporated herein by reference in their entireties.

### BACKGROUND

The present invention generally relates to a method for forming a film, and more particularly, to a method for forming a transparent electroconductive film.

As transparent electrodes to be employed in FDPs (Flat Display Panels) such as plasma display panels (PDPs) and liquid crystal panels, In—Sn—O type transparent electroconductive films (hereinafter referred to as ITO films) have been conventionally used. Since the price of indium had recently soared due to the depletion of indium sources, transparent electroconductive materials have been sought instead of ITO.

ZnO based materials have been examined as transparent electroconductive materials in place of the ITO. However, since ZnO has a high resistance, it is difficult to use ZnO alone as an electrode.

It is known that the resistivity is lowered by adding Al₂O₃ to ZnO. However, for example, when a film of a transparent electrode is formed by sputtering a target in which Al₂O₃ is added to ZnO, the resistivity of the transparent electrode is several times higher than that of the ITO film, and reduction in the resistivity is not practically sufficient.

Although the resistivity is generally lowered by heating treatment (annealing treatment) after the formation of the electroconductive film, the resistivity of the ZnO film to which Al₂O₃ was added was reversely increased by annealing in a high temperature range in the open air. See patent document No. JP A 11-236219.

### SUMMARY OF THE INVENTION

The present invention has been accomplished to solve the above problem, and is aimed at producing a transparent electroconductive film having a low resistivity by using an inexpensive and stably suppliable material.

In order to solve the above problem, the present invention is directed to a transparent electroconductive film-forming method for forming a transparent electroconductive film on a surface of an object to be film-formed by sputtering a target having ZnO as a main component in a vacuum atmosphere. The method includes: preliminarily adding a main addition oxide of Al₂O₃ to the target such that the number of atoms of a main addition element of Al is 1 or more and 5 or less per 100 atoms of Zn; selecting one or more kinds of secondary addition oxides from a secondary addition oxide group consisting of B₂O₃, Ga₂O₃, In₂O₃ and Tl₂O₃; and adding the selected secondary addition oxide or oxides to the target such that the total number of atoms of B, Ga, In or Tl in the selected secondary addition oxide or oxides is 1 or more and 15 or less per 100 atoms of Zn.

The present invention is directed to the transparent electroconductive film-forming method, wherein after the transparent electroconductive film is formed, the transparent electroconductive film is annealed by heating it at a predetermined heating temperature, and the heating temperature is set at 250° C. or more and 500° C. or less.

The present invention is directed to the transparent electroconductive film-forming method, wherein the transparent electroconductive film is heated in an open air atmosphere in the annealing.

The main component in the present invention means that the material as the main component is contained at 50 atom % or more of the total.

The present invention is provided as mentioned above, and since the Al₂O₃ (main addition oxide) and B₂O₃ (secondary addition oxide) are added to the target, the transparent electroconductive film formed by the present invention has ZnO as the main component, and Al (main addition element) and B (secondary addition element) are added thereto.

The resistivity of the ZnO film is lowered by the addition of Al, and distortion of ZnO crystals due to the addition of Al is mitigated by the addition of B. Therefore, the dopants (the total amount of Al and B) can be added at high concentrations. As a result, the resistivity of the transparent electroconductive film is lowered, as compared to a case in which no Al is added or in which only Al is added without the addition of B. Further, an effect similar to that in the case of the addition of B alone is obtained when Ga, In or Tl is added as the secondary addition element in place of B or when Ga, In or Tl is added together with B.

When Al is added alone into a film of ZnO as a donor (electron donor) at a high concentration, the electron mobility in crystals decreases, and Al, which is incorporated into the film as it is in an oxide state, increases. Consequently, the resistivity rises. According to the present invention, the reduction in the electron mobility is prevented by adding a different donor or different donors (such as, B) in addition to Al, so that the dopants can be added at high concentrations.

When the ZnO film into which Al and B are added is heated (annealed) after the film is formed by sputtering, the film is activated and the electric resistance decreases. Al is activated when Al is incorporated into the crystals in the ZnO film in the form of not an oxide but atoms. However, Al is inactivated by oxidation when the transparent electroconductive film is heated at a high temperature of 400° C. or more in the open air atmosphere. B is activated at a higher temperature than Al, and is not oxidized even at a high temperature (for example, 500° C.) in the open air atmosphere. Therefore, even when the transparent electroconductive film of the present application is heated at a high temperature, the resistivity does not increase. Al is not oxidized in a vacuum.

Ga, In and Tl are activated at a higher temperature than Al, and not oxidized at high temperatures in the open air atmosphere. Therefore, the same effect as in the case where B is added alone is obtained when Ga, In or Tl is added as the secondary addition element instead of B, or when Ga, In or Tl is added together with B.

It is presumed that when the target is used, to which Al₂O₃ and B₂O₃ are added in such a manner that the ratio of the number of the atoms of Al to that of Zn is 1% or more and 5% or less, and the ratio of the number of atoms of B to that of Zn is 1% or more and 15% or less, a transparent electroconductive film having high transparency and a low resistivity can be obtained.

The present invention can provide the transparent electroconductive film having a low resistivity by using the inexpensive and stably suppliable materials (such as, ZnO, Al₂O₃ and B₂O₃) without the use of indium. When In is used, a small addition amount of In is sufficient because In is used as the secondary addition element. Since the annealing treatment need not be performed in a vacuum atmosphere, the structure of a film-forming apparatus is simple, and the processing time in a vacuum chamber is shortened. It is presumed that when the film is obtained by heating, a similar or higher quality of the film is obtained. After the film is formed at such a temperature as causing small damage to a substrate, the resistance is lowered by the annealing treatment. Such a low temperature film-forming apparatus is simpler in structure than a high temperature film-forming apparatus.

### BRIEF DESCRIPTION OF THE DRAWING

FIG. 1 is a sectional view illustrating one example of a film-forming apparatus to be used according to the present invention.

FIGS. 2(a) and (b) are sectional views illustrating film-forming steps of the transparent electroconductive film according to the present invention.

### DETAILED DESCRIPTION OF THE EMBODIMENTS

First, an example of steps for producing a target to be used in the present invention will be explained.

Three kinds of powdery oxides of ZnO, Al₂O₃ and B₂O₃ are weighed; a mixed powder is prepared, in which ZnO is a main component and Al atoms and B atoms are contained at predetermined ratios relative to the number of atoms of Zn; and the mixed powder is preliminarily baked in a vacuum.

A mixture is prepared by adding and mixing water and a dispersant into the resulting baked material, and after the mixture is dried, it is preliminarily baked again in vacuum. Then, after the baked material is ground and homogenized, it is molded into a plate-like form in a vacuum atmosphere; and a plate-like target is prepared by baking the molded body in the vacuum atmosphere. This target has ZnO as the main component to which Al₂O₃ and B₂O₃ are added therein; and the ratios of the numbers of atoms of Zn, Al and B contained in the target are the same as in the above mixed powder.

Next, steps of forming a transparent electroconductive film by using the above target will be explained.

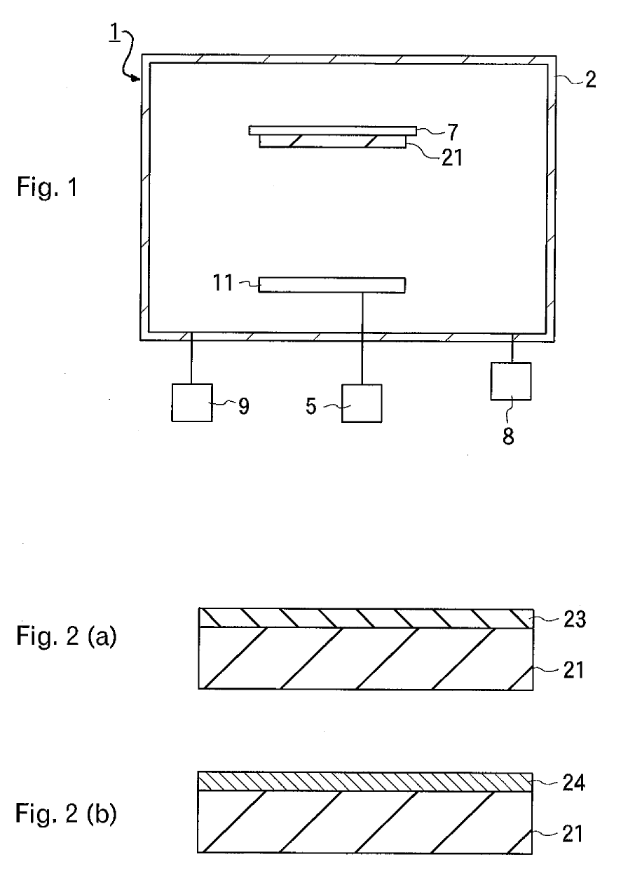

In FIG. 1, a reference numeral 1 generally indicates a film-forming apparatus to be used in the present invention. This film-forming apparatus 1 includes a vacuum chamber 2.

A vacuum evacuation system 9 and a sputtering gas feeding system 8 are connected to the vacuum chamber 2; and after the inside of the vacuum chamber 2 is evacuated to a vacuum by the vacuum evacuation system 9, a sputtering gas is fed into the vacuum chamber 2 from the sputtering gas feeding system 8, while the vacuum evacuation is being continued, thereby forming a film-forming atmosphere at a predetermined pressure.

The above-described target 11 and a substrate holder 7 are arranged inside the vacuum chamber 2; and the substrate 21 as an object to be film-formed is held by the substrate holder 7 in a state such that a surface thereof is directed so as to be opposed to the target 11.

The target 11 is connected to an electric power source 5 arranged outside the vacuum chamber 2. When a voltage is applied to the target 11 in a state such that the vacuum chamber 2 is set at a ground potential while the above film-forming atmosphere is being maintained, the target 11 is sputtered to discharge sputtered particles. A transparent electroconductive film 23 is grown on the surface of the substrate 21 such that in the transparent electroconductive film 23, ZnO is a main component and the ratios of the number of atoms of Zn, that of Al and that of B are the same as in the target 11 (See FIG. 2(a)).

The film formation is stopped at a time when the transparent electroconductive film 23 grows to a predetermined film thickness; and the substrate 21 is taken out from the film-forming apparatus 1 to the open air atmosphere. The substrate 21 on which the transparent electroconductive film 23 is formed is carried into a heater (not shown); and the transparent electroconductive film 23 is annealed by heating at a predetermined annealing temperature in the open air atmosphere. In FIG. 2(b), a reference numeral 24 indicates a transparent electroconductive film having undergone the annealing treatment. Since the annealed transparent electroconductive film 24 has a low resistivity, it can be used as a transparent electrode for an FDP when that transparent electroconductive film 24 is patterned in a predetermined shape.

Unlike the ITO, the transparent electroconductive film of the present invention can be patterned even after the annealing treatment.

### EXAMPLES

After a target 11 was prepared under the following “Preparation condition”, a transparent electroconductive film 24 in Example 1 was formed on a surface of a substrate under the following “Film-forming condition” by using the target 11.

### <Preparation Condition>

Composition of a mixed powder: the number of atoms of Al=3 and that of B=6 (per 100 atoms of Zn)

Preliminary baking (first and second times): 450° C. in a vacuum atmosphere for 12 hours

Preparation of a mixture: mixed in a ball mill for 24 hours by using zirconia balls 10 φ (particle diameter 10 mm)

Drying of the mixture: dried in an oven for 48 hours

Grinding: manually ground to 750 μm or less in particle diameter by using a mortar

Molding and baking of the target: molded and baked at 600° C. for 150 minutes in a vacuum by hot press

Size of the target: 4 inches in diameter

### <Film-Forming Condition>

Temperature of the substrate: 160° C.

Film thickness: 200 nm (2000 Å)

Sputtering gas: Ar

Flow rate of Ar: 200 sccm

Pressure of a film-forming atmosphere: 0.4 Pa

Voltage applied to the target: 0.8 kW (DC power source)

Annealing temperature: 200 or more and 400° C. or less (in the open air atmosphere)

### <Resistivity Measurement>

As to the transparent electroconductive film 24 in Example 1 after the annealing treatment, the resistivity was measured by a 4-probe low resistivity meter.

A transparent electroconductive film in the Comparative Example was prepared under the same condition as in the above Example 1 except that a target in which ZnO was a main component and 2 wt % of Al₂O₃ was added (no B contained) was used; and the resistivity of the transparent electroconductive film was also measured under the same condition as in Example 1.

Measurement results thereof are given in the following table 1 together with the annealing temperatures.

TABLE 1
Table 1: Measurement of resistivity

| | Resistivity [μΩ · cm] | | | | | |
|---|---|---|---|---|---|---|
| | Before | After annealing in open air for 1 hour | | | | |
| Target | annealing | 200° C. | 250° C. | 300° C. | 350° C. | 400° C. |
| Example 1 | 2782 | 986 | 720 | 578 | 492 | 512 |
| Comparative | 1085 | 686 | 645 | 672 | 675 | 590000 |
| Example | | | | | | |

As the transparent electrode for the FDP, the resistivity is preferably around 500 μ Ω·cm or less. The measurement results are shown in Table 1 such that when the annealing temperature is 300° C. or more and 400° C. or less, Example 1 shows lower in terms of resistivity than that of Comparative Example, and its resistivity is so low that the resistivity is less than 600 μ Ω·cm and near 500 μ Ω·cm. Further, the above results show that the film obtained in Example 1 is transparent and is optically and electrically suitable as a transparent electrode.

On the other hand, the resistivity in Comparative Example exceeded 600 μ Ω·cm even when the annealing temperature was varied; and particularly with respect to the film annealed at the annealing temperature of 400° C. or more, the oxidation of the transparent electroconductive film proceeded, and the degradation of the resistance was distinguished. To the contrary, the resistivity of the transparent electroconductive film 24 in Example 1 did not significantly increase even when the annealing temperature was 400° C.

The above results show that if the transparent electroconductive film formed by sputtering the target, in which ZnO is a main component and Al₂O₃ and B₂O₃ are added to ZnO, is annealed at a temperature of 300° C. or more and 400° C. or less, the film suitable for the transparent electrode can be obtained.

The above explanation has been made for the case where Ar gas is used as the sputtering gas, but the invention is not limited thereto. As the sputtering gas, a Xe gas, a Ne gas or the like can be used.

The method for producing the target 11 is not particularly limited, and the target 11 to be used in the present application can be produced by a variety of producing methods that are ordinarily employed.

When the annealing treatment is performed in the vacuum atmosphere, the resistivity becomes lower as compared with the case where it is done in the open air atmosphere. However, since a vacuum chamber to be exclusively used for the annealing treatment needs to be prepared for annealing in the vacuum atmosphere, the film-forming apparatus becomes complicated and expensive. Moreover, as the processing time inside the vacuum chamber becomes longer due to the annealing time, the time required for the formation of a film on a single substrate is longer as compared to the case where the annealing is done in the open air atmosphere.

As described above, according to the present invention, even when the annealing treatment is performed in the open air atmosphere, the resistivity is decreased practically sufficiently as the transparent electrode, so that the annealing treatment is preferably performed in the open air atmosphere.

The transparent electroconductive films 24 formed by the present invention can be used as transparent electrodes for various kinds of display devices such as an FED (Field Emission Display) or the like besides the transparent electrodes for the PDP and the liquid crystal panel. Since no problem occurs in the producing process in the cases of the FED and the PDP even if the annealing temperature is set at a high temperature of 300° C. or more, the invention of this application is particularly suitable for the production of the transparent electrodes in these display apparatuses.

If optimum ranges of an addition amount of Al₂O₃ (the ratio of the number of atoms of Al to that of Zn) and an addition amount of B₂O₃ (the ratio of the number of atoms of B to that of Zn) to be added respectively to the target are found, it is presumed that even if the annealing temperature is less than 300° C., a low resistivity can be attained.

### Example 2

A target 11 in Example 2 was prepared under the same condition as in the above Example 1 except that addition amounts of Al₂O₃ and B₂O₃ were changed. After a transparent electroconductive film 23 was formed under the same condition as in the above Example 1 by using the target 11, an annealed transparent electroconductive film 24 was obtained by heating in a temperature range of 200° C. to 500° C. in the open air atmosphere.

Resistivities of the annealed transparent electroconductive film 24 and the transparent electroconductive film 23 before the annealing were measured by the method described in the above “Resistivity measurement”.

The target 11 of Example 2 is composed of ZnO, Al₂O₃, B₂O₃, and the following Table 2 shows the relationships among the numbers of the atoms of the respective components per 100 atoms of the components composing the target 11 (figures in a column of Ratios of components of target), heating temperatures and resistance values.

TABLE 2
Table 2: Ratios of components of target, heating temperature and resistivity

| | Ratios of components | | | Resistivity (μΩ · cm) | | | | | | | |
|---|---|---|---|---|---|---|---|---|---|---|---|
| | of target | | | Before | Heating in open air for 1 hour | | | | | | |
| | Zn0 | Al₂0₃ | B₂0₃ | annealing | 200° C. | 250° C. | 300° C. | 350° C. | 400° C | 450° C. | 500° C. |
| Example 2 | 95.5 | 1.5 | 3.0 | 1026 | 764 | 523 | 359 | 351 | 472 | 541 | 52000 |

“O.L” in the above Table 2 indicates “over the range”, which shows that the resistivity is so high that it cannot be measured by the above-mentioned low resistivity meter.

The above Table 2 shows that when the target 11 in Example 2 is used, the results of the Table 2 does not exhibit “over the range” even at the heating temperature of 500° C.; and thus, the low resistivities can be obtained at 200° C. or more and 500° C. or less.

When the transparent electroconductive films formed by using the target in the above Comparative Example were heated at 450° C. or 500° C., the resistivities were over the range.

The numbers of atoms of Al and B contained in the respective components per 100 atoms of Zn in the target 11 were determined from the ratios of the components of the target shown in Table 2, and they were taken as the contents of the elements. The contents of the elements in Example 2 are as given in the following Table 3.

TABLE 3
Table 3: Contents of elements

| | Contents of elements | | |
|---|---|---|---|
| | Zn | Al | B |
| Example 2 | 100 | 3.14 | 6.28 |

From the above Table 3 and the above Example 1, according to Examples 1 and 2, the number of the atoms of the main addition element (Al) is 3 or more and 3.14 or less relative to 100 atoms of Zn; and the number of the atoms of the secondary addition element (B) is 6 or more and 6.28 or less relative to 100 atoms of Zn.

Although the case has been explained above in which B₂O₃ was added as the secondary addition oxide to the target 11, the invention is not limited thereto.

One or more kinds of the secondary addition oxides selected from the secondary addition oxide group consisting of B₂O₃, Ga₂O₃, In₂O₃ and Tl₂O₃ may be added to the target 11 together with Al₂O₃ as the main addition oxide. In this case, the total number of the atoms of the secondary addition elements (B, Ga, In and Tl) of the secondary addition oxides added to the target is set at 1 or more and 15 or less relative to 100 atoms of Zn.

Heating of the transparent electroconductive film 23 is not limited to the heating in the open air atmosphere; and the transparent electroconductive film 23 may be heated during the film-formation in the vacuum atmosphere or the transparent electroconductive film 23 may be heated in the vacuum atmosphere after the formation of the film.

Main causes for the resistance degradation are that the ionized carrier is oxidized, the oxygen-lacking state cannot be maintained due to the oxidation, and the film does not function as an n-type semiconductor. Therefore, it is clear that for the purpose of reducing the resistance, the high-temperature heating in the open air atmosphere is the severest condition as compared to the case of the heating during the film formation and the case of the heating in the vacuum atmosphere.

No resistance degradation occurs, even when the annealing temperature in the vacuum atmosphere is set higher than the annealing temperature in the open air atmosphere (for example, 500° C. or more). When the heating is performed during the film formation, the quality of the film can be obtained, which is equivalent to or higher than the annealing in the open air atmosphere.

What is claimed is:

1. A transparent electroconductive film-forming method for forming a transparent electroconductive film on a surface of an object to be film-formed by sputtering a target having ZnO as a main component in a vacuum atmosphere, the method comprising:
preliminarily adding a main addition oxide of Al₂O₃ to the target such that the number of atoms of a main addition element of Al is at least 1 and at most 5 per 100 atoms of Zn,
selecting at least one kind of secondary addition oxides from a secondary addition oxide group consisting of B₂O₃, Ga₂O₃, In₂O₃ and Tl₂O₃, and
preliminarily adding the selected secondary addition oxide or oxides to the target such that the total number of atoms of B, Ga, In or Tl in the selected secondary addition oxide or oxides is at least 1 and at most 15 per 100 atoms of Zn.

2. The transparent electroconductive film-forming method according to claim 1, wherein after the transparent electroconductive film is formed, the transparent electroconductive film is annealed by the heating thereof at a predetermined heating temperature, and the heating temperature is set at at least 250° C. and at most 500° C.

3. The transparent electroconductive film-forming method according to claim 2, wherein the transparent electroconductive film is heated in an open air atmosphere in the annealing.
